(19) United States
(12) Patent Application Publication
(10) Pub. No.: US 2012/0006390 A1
(43) Pub. Date: Jan. 12, 2012

(54) Nano-wire solar cell or detector

(76) Inventors: Yijie Huo, Mountain View, CA (US); Anjia Gu, Menlo Park, CA (US); James S. Harris, JR., Stanford, CA (US); Shu Hu, Stanford, CA (US); Paul C. Mclntyre, Sunnyvale, CA (US)

(21) Appl. No.: 13/065,710

(22) Filed: Mar. 28, 2011

Related U.S. Application Data
(63) Continuation-in-part of application No. 12/928,278, filed on Dec. 7, 2010, now abandoned.
(60) Provisional application No. 61/283,812, filed on Dec. 8, 2009.

(51) Int. Cl. H01L 31/0352; H01L 31/18

(52) U.S. Cl. 136/255; 438/57; 257/14; 257/E31.001; 257/E31.032

(57) ABSTRACT

Solar cells or photodetectors having one or more single-crystal shell layers conformally deposited on Ge nano-wires are provided. This approach can provide higher efficiency and/or reduced material cost compared to conventional planar approaches for multi-junction solar cells having the same thickness of active solar absorption materials. Shell layers deposited on the Ge nano-wires and including pn junctions can be grown such that they end up with single-crystal faceted tips, which can significantly improve optical collection efficiency and can improve the electron collection efficiency because of the high crystal quality.

### CROSS REFERENCE TO RELATED APPLICATIONS

This application is a continuation in part of U.S. application Ser. No. 12/928,278, filed on Dec. 7, 2010, entitled “Nano-wire solar cell or detector”, and hereby incorporated by reference in its entirety. Application Ser. No. 12/928,278 claims the benefit of U.S. provisional patent application 61/283,812, filed on Dec. 8, 2009, entitled “Nano-structured solar cell or detector”, and hereby incorporated by reference in its entirety.

### FIELD OF THE INVENTION

This invention relates to photovoltaic devices, such as solar cells and detectors.

### BACKGROUND

Increasing the efficiency of solar cells has been the subject of intensive research and development for many years. Although numerous solar cell approaches have been proposed and developed, the goal of providing solar cells having both high efficiency and low cost remains elusive. Semiconductor photovoltaic devices have been investigated for many years in connection with solar cell applications. Such devices are based on the appearance of a voltage at the terminals of an illuminated pn junction. More recently, multi-junction devices have been considered, which include several pn junctions in series, each junction covering a different part of the solar spectrum.

Variations of device geometry have also been considered. For example, solar cells including nano-wires in various configurations have been considered for improving solar cell efficiency. Representative examples in the art include U.S. Pat. No. 7,741,647, US 2004/0109666, and US 2008/0169017.

### SUMMARY

In the present work, photovoltaic cell efficiency is addressed by using Ge nano-wires as the substrate for photovoltaic cells. Such photovoltaic cells can be homojunction or heterojunction devices, and can be single-junction or multi-junction. The photovoltaic cells can employ p-n and/or p-i-n junctions. The photovoltaic cells can be single-crystal or poly-crystalline. Suitable semiconductors for the photovoltaic cells include group IV elements and alloys, group III-V compounds and alloys, and group II-VI compounds and alloys. The Ge nano-wires can be disposed on an inexpensive and/or flexible substrate (e.g., Aluminum foil). For example, an amorphous or polycrystalline Ge layer can be deposited on Al foil, and then Al or Ga can be used as a catalyst to grow Ge nano-wires on the Ge layer. Growth of Ge thin films on both glass and polymer substrates has been demonstrated by Hu, Marshall and McIntyre in an article entitled “Interface-controlled layer exchange in metal-induced crystallization of germanium thin films” (Applied Physics Letters 97, 082104, (2010)), hereby incorporated by reference in its entirety. Authors Hu and McIntyre of this reference are also inventors of the present application. Other suitable substrates include, but are not limited to silicon, glass, and polymers.

The use of Ge nano-wires allows the use of inexpensive substrates, and provides a favorable device geometry for solar cell operation (i.e., photo-generated carriers are relatively close to device electrodes, reducing recombination loss). Shell layers deposited on the Ge nano-wires and including pn junctions can be grown such that they end up with faceted tips, by sophisticated pre-growth treatment and growth condition tuning. Faceted tips provide two main advantages: 1) they provide direct evidence that the overgrown structures are single crystalline, and 2) they can significantly improve optical collection efficiency.

The present approach provides several significant advantages. Solar cell efficiency can be improved because the Ge nano-wires can serve as small band-gap absorption layers in close proximity to the photovoltaic cells. Solar cell cost can be dramatically reduced because inexpensive substrates can be employed. For example flexible and/or ultra-light substrates can be employed that are compatible with a roll-to-roll fabrication process, which can reduce cost by increasing process throughput. Solar cell installation can also be reduced by the use of flexible/light substrates. Such solar cells can be included on wearable materials (e.g., on clothing to provide power to personal electronic devices).

Applications of the present approach include general photovoltaic applications, solar farms, building installations (e.g., roof, curtain, windows, etc.). Further applications include providing power to wearable devices such as helmets and backpacks. Providing emergency charger and/or power supply capability for field applications is also possible. The present approach is also applicable to photodetectors, in addition to solar cells.

### BRIEF DESCRIPTION OF THE DRAWINGS

FIG. 1a shows an embodiment of the invention.

FIG. 1b shows a close up view of the example of FIG. 1a.

FIGS. 2a-f show a fabrication sequence for an embodiment of the invention.

FIG. 3 shows another embodiment of the invention.

FIGS. 4-6 show simulation results pertaining to an embodiment of the invention.

FIGS. 7a-c show SEM images of Ge nano-wires (a) and overgrown GaAs—Ge shell-core structure (b and c).

FIGS. 8a-c show SEM images of completed devices.

FIG. 9 shows an embodiment of the invention including a photovoltaic cell on a wearable material.

### DETAILED DESCRIPTION

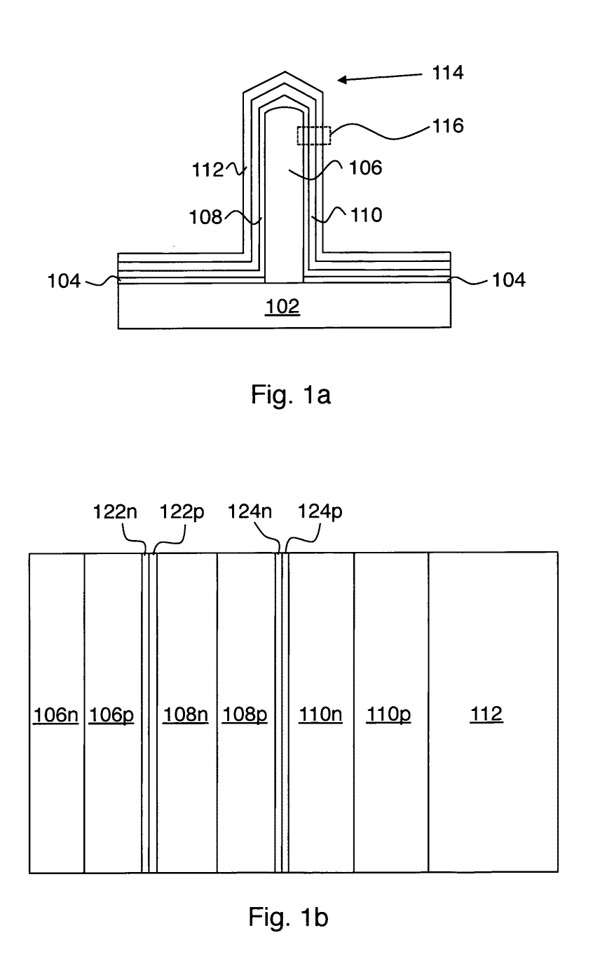

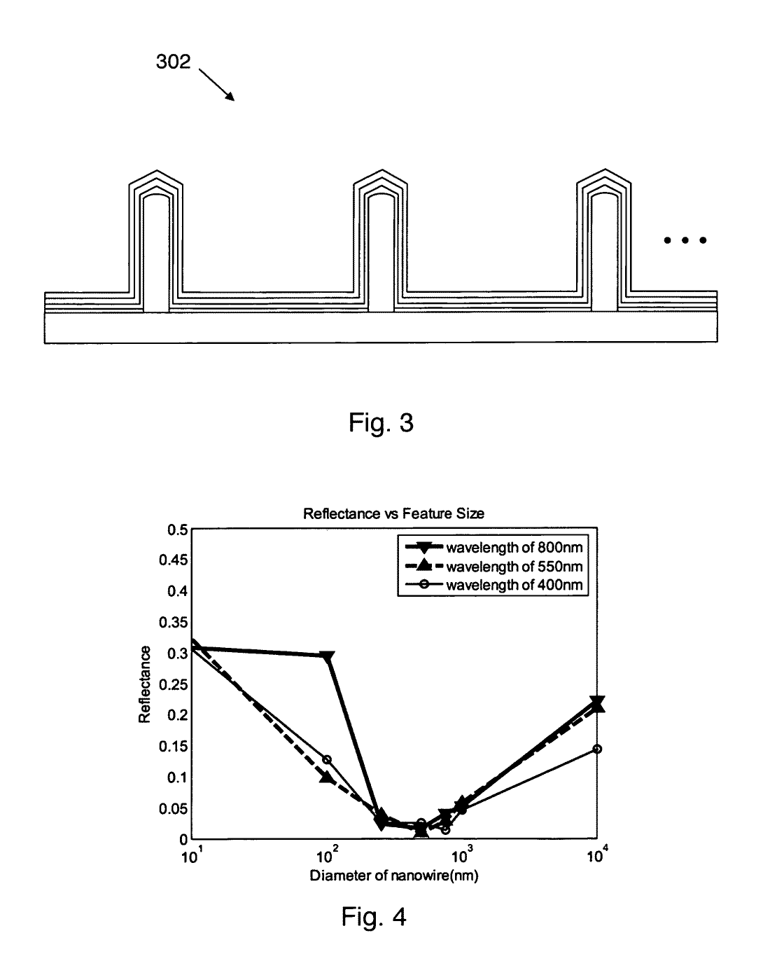

FIG. 1a shows a close-up view of an embodiment of the invention. In this example, a Ge nano-wire 106 is epitaxially grown on a substrate 102 (e.g., Si). A first junction layer 108 is disposed on nano-wire 106, and a second junction layer 110 is disposed on first junction layer 108. A transparent conductive layer 112 (e.g., indium tin oxide) is disposed on second junction layer 110. First junction layer 108 is insulated from substrate 102 by an insulating layer 104 (e.g., SiO₂). One or more of the shell layers has a faceted tip 114, as shown on FIG. 1b. As described below, this feature can improve optical collection efficiency. Note that the Ge nano-wires typically do not have faceted tips, so the faceting is a feature of the shell layer(s). In a typical device, numerous nano-wires are present, each having this layer structure, e.g. as indicated by 302 on FIG. 3.

A structure as in FIG. 1a can be a two junction solar cell, where a pn junction is formed in each of the junction layers 108 and 110. Three junction solar cells can also be formed with this structure by doping the Ge nano-wire to form a third pn junction, in addition to the pn junctions in layers 108 and 110. Each pn junction can be connected with a tunnel junction, where electrons or holes move through by quantum tunneling. Such tunnel junctions function as Ohmic contacts within a semiconductor device, and also change the minority carriers to majority carriers (e.g. electrons to holes if the minority carriers are electrons, or vice versa.). For example, such a tunnel junction connection can be made at the interface between layers 106 and 108 by heavy and opposite doping of the two sides of the interface. Similar tunnel junctions can also be formed at other interfaces in the structure.

An example of this kind of 3-junction device is shown in the further close up view of FIG. 1b. Here, regions 106n and 106p are n and p regions of layer 106 respectively. Similarly, regions 108n and 108p are n and p regions of layer 108 respectively, and regions 110n and 110p are n and p regions of layer 110 respectively. Tunnel junctions as described above are provided by layers 122n and 122p, which are heavily doped n and p type respectively, and by layers 124n and 124p, which are heavily doped n and p type respectively.

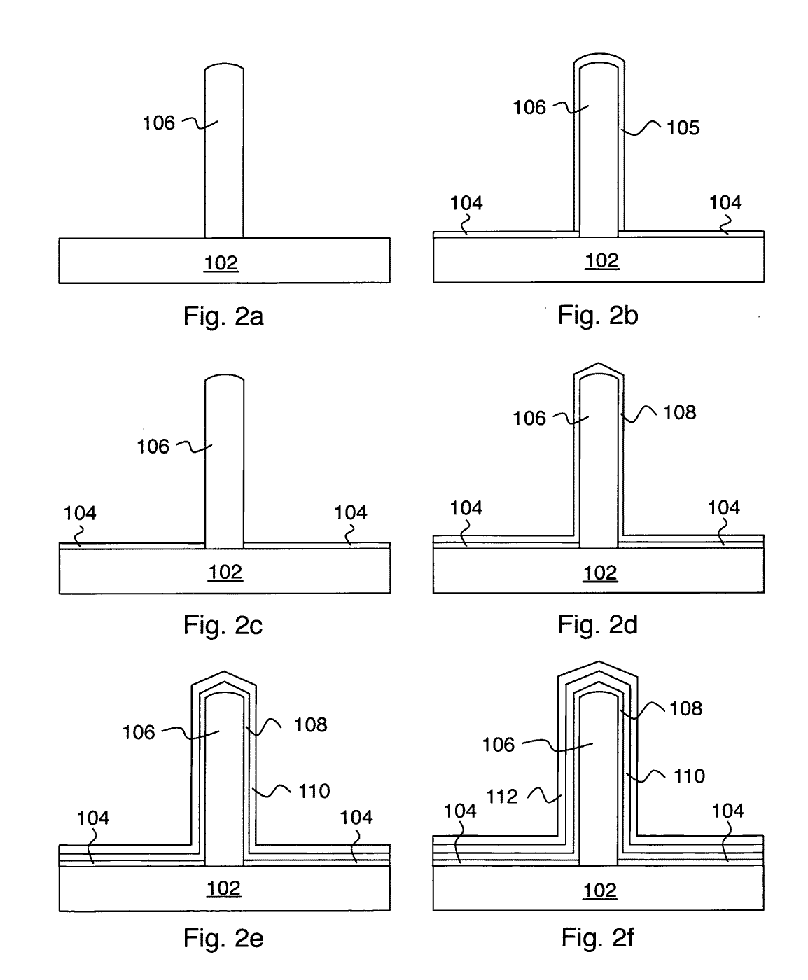

An exemplary fabrication sequence for the structure of FIG. 1a is shown on FIGS. 2a-f. FIG. 2a shows the result of growing Ge nano-wires 106 on a Si substrate 102. FIG. 2b show the result of oxidizing the structure of FIG. 2a. More specifically, GeOₓ 105 forms on the Ge nano-wire, and SiOₓ 104 forms on the Si substrate. FIG. 2c shows the result of selectively etching the structure of FIG. 2b. The etch for this step should remove GeOₓ, but not remove SiOₓ or Ge. Suitable recipes for such a selective etch are known in the art. Optionally, dopants can be incorporated during growth or diffused after growth into the Ge nano-wires to form a pn junction in the nano-wires. FIG. 2d shows the result of conformally depositing a first junction layer 108 on nano-wire 106. FIG. 2e shows the result of conformally depositing a second junction layer 110 on top of first junction layer 108. Finally, FIG. 2f shows the result of depositing a transparent conductive layer 112 on the structure of FIG. 2e.

### Simulation Results and Experimental Results:

Conventionally, III-V multijunction solar cells have multiple planar layers on single-crystal Ge or GaAs or other lattice matched single-crystal III-V substrates. In this work, we report our recent discovery that the surface kinetics and epitaxial growth by MBE are dramatically altered when growing on nano-wires instead of planar surfaces. These growth kinetics enable uniform, single-crystal growth of low-defect, lattice matched or mismatched materials on nano-wires with high aspect ratios. We have also found that the GaAs layers can be grown on Ge nano-wires independent of substrate material, enabling the usage of flexible and low cost substrates.

### Simulation Results

Nano-wire structures can greatly improve the light absorption over a wide range of spectra and incident angle.

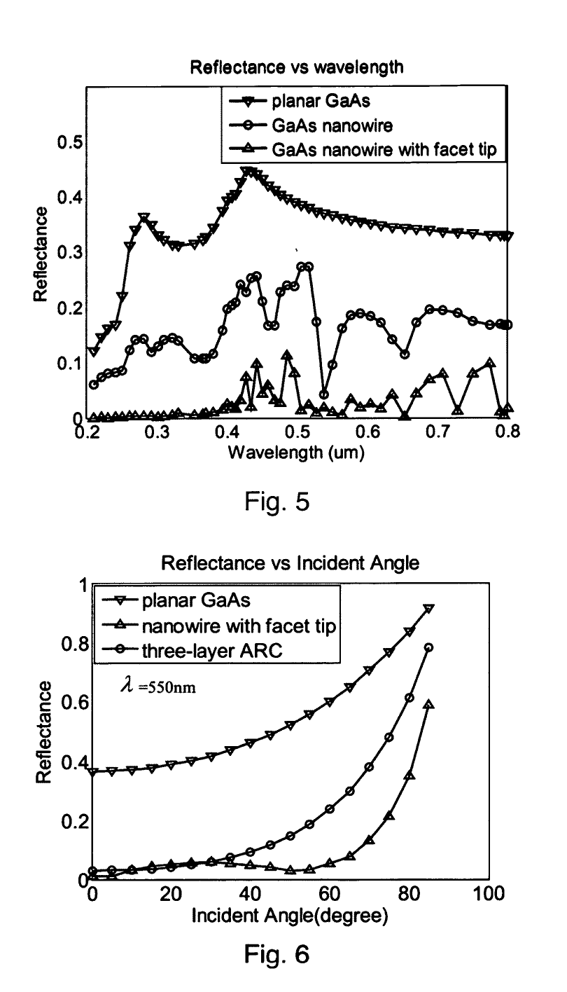

We simulate the reflection of nano-wire arrays over a large range of diameter size using rigorous coupled wave analysis (RCWA) method. For most wavelengths in sun spectra, the reflectance is below 5% when the diameter of nano-wire is in the range of several hundreds nanometers (FIG. 4). In FIG. 5, the planar GaAs solar cell without antireflection coating (ARC) has more than 30% reflectance; for nano-wires with facet tip, the reflectance is reduced by more than 5-fold (FIG. 5). These nano-wire solar cell arrays accept much wider angle of incidence of sun light than the planar cell with and without ARC. As in FIG. 6, the reflectance is below 15% from 0° to 70° for the nano-wire arrays; while for planar cells and three-layer ARC, the reflectance is 70% and 38% at the incident angle of 70°.

### Experimental Results

The relevant device structure for this example is illustrated in FIG. 1a. The first pn junction layer 108 is a GaAs layer and is conformally grown on Ge nano-wires pre-grown on SOI (Silicon on Insulator) wafers via VLS (Vapor-Liquid-Solid) method. The second pn junction layer 110 can include wider-bandgap material, such as AlGaAs or InGaP, lattice-matched to GaAs. A window layer and a heavily doped contact layer can be grown to reduce surface recombination and contact resistance. After surface passivation, a conformal transparent contact (TCO) layer of tin-doped indium oxide (ITO) is deposited. Because the total thickness of all layers is about 2 μm, the multijunction 3-D structure can be transferred to a thin metal foil after the patterned structure is etched off from the SOI wafer at the buried dielectric layer. Thus, the whole solar cell arrays can have significant mechanical flexibility and transferability to curved surfaces.

The single-crystal Ge/GaAs and Ge/AlGaAs core-shell nano-wire structure have been fabricated by MBE. The Ge nano-wires are grown on Si substrates via a vapor-liquid-solid method and then the catalysts are removed before loading in to a Veeco Gen II MBE system. The sample is baked at 350° C. in the baking chamber and then loaded into the growth chamber where the base pressure is ˜10⁻¹⁰ Torr. Ge oxide is blown off ˜500° C. (thermocouple reading) for 5 minutes. After that, GaAs is grown at 0.3 μm/hour with As overpressure ˜400° C. The Ge nano-wire (111) crystal and enhanced surface mobility at sharp curvatures allow us to achieve a good single crystal GaAs shell overgrown on Ge nano-wire. Clear single-crystal hexagonal pillars are obtained. SEM and TEM measurements confirm that the GaAs/Ge core-shell structure is single crystal. Al_{0.5}Ga_{0.5}As single crystal shell overgrowth on Ge nano-wire is also achieved under similar conditions at slightly higher growth rate. More surface roughness is observed and may be due to the high Al concentration. We also derive the ratio of growth rate of nano-wire side wall thickness (rₛ) over that of planar 2D growth (r_{b}) is rₛ:r_{b}=(tan Φ)/π, where Φ is the angle between the Ga flux and the axis of nano-wire. This growth rate prediction fits the SEM measurement results very well. Finally, the transparent contact layer (TCO) is deposited by sputtering, showing good conformality and uniformity.

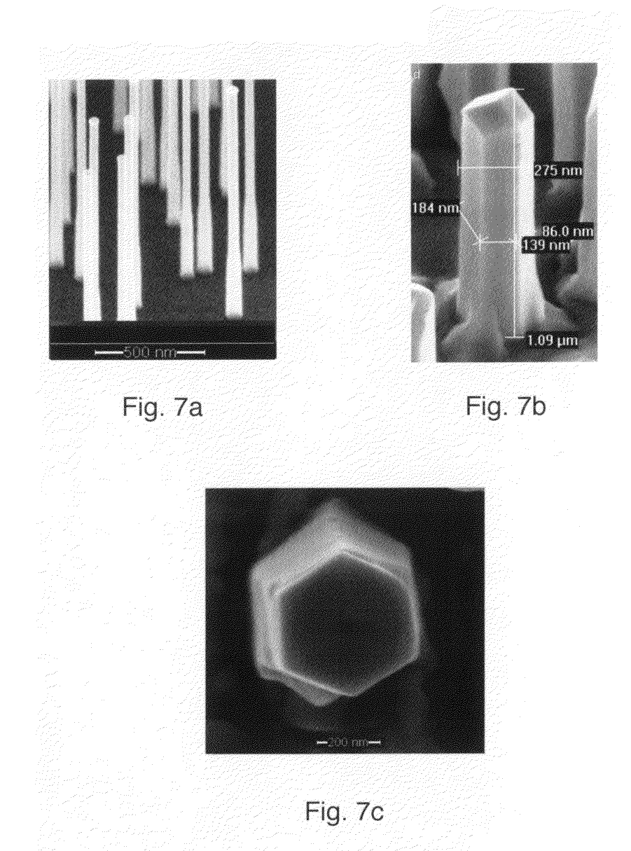

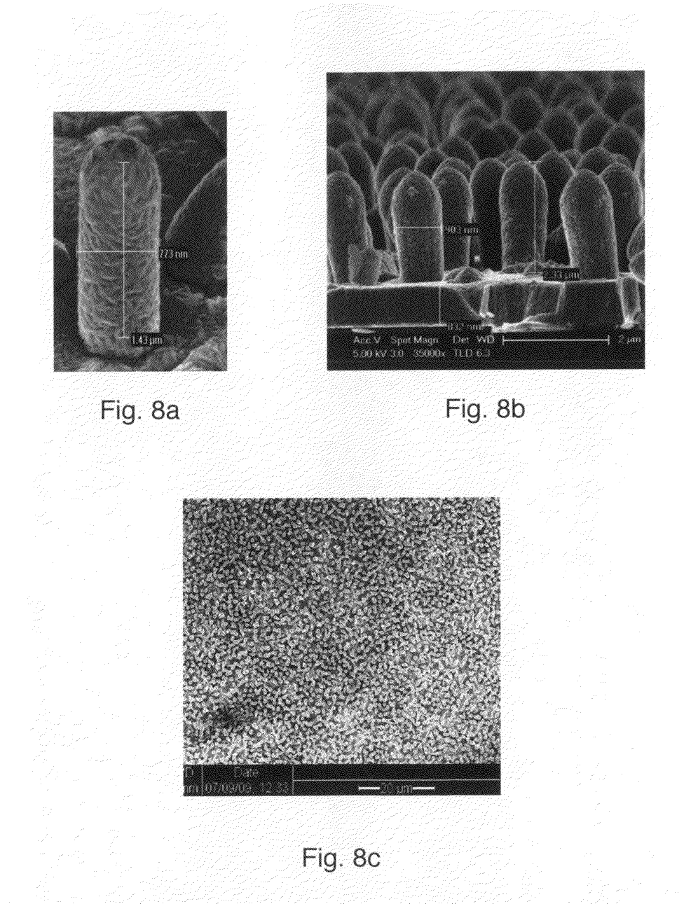

FIGS. 7a-c and 8a-c show scanning electron microscope images at various points in a fabrication process. FIG. 7a shows Ge nano-wires. FIG. 7b shows a close-up view of a nano-wire after deposition of a GaAs first junction layer on a Ge nano-wire. We have found that growth of the first junction layer on a Ge nano-wire tends to provide a faceted tip as seen on FIG. 7b. This faceting is advantageous for solar cell applications, since it provides efficient collection of solar energy over a wider range of incident angles (FIG. 6), thereby improving efficiency and/or reducing cost by eliminating solar tracking. FIG. 8a shows a single nano-wire after deposition of the ITO, FIG. 8b shows a tilted view of the nanowire solar cell arrays after ITO deposition, and FIG. 8c shows a top view of the dense arrays after ITO deposition.

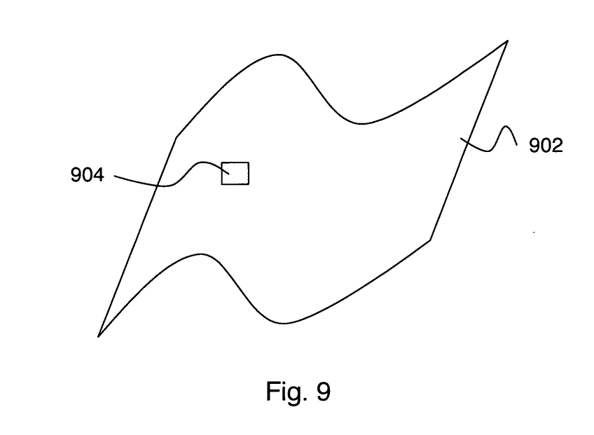

FIG. 9 shows a wearable material 902 including one or more photovoltaic devices 904 as described above. The use of flexible and inexpensive substrates as described above significantly facilitates this application. Here device 904 can be any kind of photovoltaic device, such as a solar cell or photodetector.

1. A photovoltaic device comprising:
a substrate
one or more Ge nano-wires disposed vertically on the substrate; and
one or more shell layers epitaxially disposed on the nano-wires;
wherein at least one pn junction is formed in or between the shell layers; and
wherein at least one of the shell layers has a faceted tip.

2. The photovoltaic device of claim 1, further comprising one or more insulation layers disposed between the substrate and the one or more shell layers.

3. The photovoltaic device of claim 1, wherein the Ge nano-wires are single-crystal nano-wires.

4. The photovoltaic device of claim 1, further comprising one or more tunnel junctions formed by the shell layers.

5. The photovoltaic device of claim 1, wherein the substrate is electrically passive and is not included in any pn junction of the photovoltaic device.

6. The photovoltaic device of claim 1, wherein the substrate comprises a flexible material.

7. The photovoltaic device of claim 1, wherein the substrate comprises a material selected from the group consisting of: metal foils, silicon, glass, and polymers.

8. A wearable material comprising the photovoltaic device of claim 1.

9. A solar cell comprising the photovoltaic device of claim 1.

10. A photodetector comprising the photovoltaic device of claim 1.

11. A method of making a photovoltaic device, the method comprising:
providing a substrate;
disposing one or more Ge nano-wires vertically on the substrate; and
epitaxially growing one or more shell layers on the nano-wires such that at least one of the shell layers has a faceted tip;
wherein at least one pn junction is formed in or between the shell layers.
